(19) United States
(12) Patent Application Publication
(10) Pub. No.: US 2019/0207101 A1
(43) Pub. Date: Jul. 4, 2019

(54) PHOTOLITHOGRAPHIC METHOD FOR FABRICATING DENSE PILLAR ARRAYS USING SPACERS AS A PATTERN

(71) Applicant: SPIN TRANSFER TECHNOLOGIES, INC., Fremont, CA (US)

(72) Inventors: Prachi Shrivastava, Fremont, CA (US); Yuan Tung Chin, Fremont, CA (US); Thomas Boone, Fremont, CA (US); Mustafa Pinarbasi, Fremont, CA (US)

(21) Appl. No.: 15/857,499

(22) Filed: Dec. 28, 2017

(51) Int. Cl. H01L 43/12; H01L 27/22

(52) U.S. Cl. CPC H01L 43/12; H01L 43/08; H01L 27/222

(57) ABSTRACT

A method for fabricating an array of pillars. The method includes fabricating a plurality of lines of photoresist on a hard mask stack and depositing a spacer film on top of the plurality of lines of photoresist. The method further includes etching the spacer film to remove the spacer film from the top of the plurality of lines of photoresist and stripping the plurality of lines of photoresist to leave behind to spacer lines for each resist line. The method concludes with etching the spacer lines and the hard mask stack to yield an array of pillars.

### FIELD OF THE INVENTION

Embodiments of the present invention are generally related to the fabrication of integrated circuit structures used in memory systems that can be used by computer systems, including embedded computer systems.

### BACKGROUND OF THE INVENTION

Magnetoresistive random-access memory (“MRAM”) is a non-volatile memory technology that stores data through magnetic storage elements. These elements are two ferromagnetic plates or electrodes that can hold a magnetic field and are separated by a non-magnetic material, such as a non-magnetic metal or insulator. This structure is known as a magnetic tunnel junction (MTJ).

MRAM devices can store information by changing the orientation of the magnetization of the free layer of the MTJ. In particular, based on whether the free layer is in a parallel or anti-parallel alignment relative to the reference layer, either a one or a zero can be stored in each MRAM cell. Due to the spin-polarized electron tunneling effect, the electrical resistance of the cell change due to the orientation of the magnetic fields of the two layers. The electrical resistance is typically referred to as tunnel magnetoresistance (TMR) which is a magnetoresistive effect that occurs in a MTJ. The cell's resistance will be different for the parallel and anti-parallel states and thus the cell's resistance can be used to distinguish between a one and a zero. One important feature of MRAM devices is that they are non-volatile memory devices, since they maintain the information even when the power is off.

MRAM devices are considered as the next generation structures for a wide range of memory applications. MRAM products based on spin torque transfer switching are already making its way into large data storage devices. Spin transfer torque magnetic random access memory (STT-MRAM), or spin transfer switching, uses spin-aligned (polarized) electrons to change the magnetization orientation of the free layer in the magnetic tunnel junction. In general, electrons possess a spin, a quantized number of angular momentum intrinsic to the electron. An electrical current is generally unpolarized, e.g., it consists of 50% spin up and 50% spin down electrons. Passing a current though a magnetic layer polarizes electrons with the spin orientation corresponding to the magnetization direction of the magnetic layer (e.g., polarizer), thus produces a spin-polarized current. If a spin-polarized current is passed to the magnetic region of a free layer in the MTJ device, the electrons will transfer a portion of their spin-angular momentum to the magnetization layer to produce a torque on the magnetization of the free layer. Thus, this spin transfer torque can switch the magnetization of the free layer, which, in effect, writes either a one or a zero based on whether the free layer is in the parallel or anti-parallel states relative to the reference layer.

The fabrication of MRAM involves the formation of small MTJ (Magnetic Tunnel Junction) patterns in pillar shapes. The pillars or pillar structures can be patterned on a hard mask layer and then transferred to an MTJ film metal stack. The patterning of pillars on a hard mask layer is traditionally done using an electron beam in a research environment. However, for high volume production, electron beam patterning is not cost effective as the process is very slow. Alternately, these pillars can be patterned using optical lithography tools.

In such a patterning process, the initial resist pattern determines the pitch and the critical dimension (CD) of the pattern. Different tools such as optical lithography and electron beam lithography can be utilized to create a pillar pattern on the wafers. Most commonly used tools in a high volume manufacturing are optical lithography tools. These photolithography tools have different optical wavelength constraints. For smaller feature sizes, smaller wavelength tools are used. However, the feature size is limited by the tools available.

Thus what is needed is a fabrication method in which the pattern density of the pillars can be increased beyond the limitations of photolithography tools. There are techniques which are known for line and space patterning. What is further needed is a technique which extends the density of pillar patterning for MRAM MTJ applications.

### SUMMARY OF THE INVENTION

Embodiments of the present invention provide a fabrication method in which the pattern density of the pillars can be increased beyond the limitations of photolithography tools. Embodiments of the present invention advantageously utilize techniques which are known for line and space patterning. Embodiments of the present invention implement a technique which extends the density of pillar patterning for MRAM MTJ applications.

Embodiments of the present invention implement a method for fabricating an array of pillars. The method includes fabricating a plurality of lines of photoresist on a hard mask stack and depositing a spacer film on top of the plurality of lines of photoresist. The method further includes etching the spacer film to remove the spacer film from the top of the plurality of lines of photoresist and stripping the plurality of lines of photoresist to leave behind two spacer lines for each resist line. The method concludes with etching the spacer lines and the hard mask stack to yield an array of pillars.

In one embodiment, the hard mask stack comprises a multilayer hard mask stack. In one embodiment, the multilayer hard mask stack includes a bottom antireflective coating layer (BARC).

In one embodiment, reactive ion etching (ME) etches the hard mask stack to form hard mask pillars on top of an MTJ metal stack. In one embodiment, the hard mask stack comprises a multilayer hard mask stack comprising a bottom antireflective coating (BARC) layer, a first hard mask layer, and a second hard mask layer.

In one embodiment, the hard mask layers may comprise many different materials (e.g., tantalum nitride, silicon oxide, or the like). In one embodiment, wafers produced using photolithography patterning proceed through a subsequent MTJ fabrication process.

In one embodiment, the present invention is implemented as a method for producing pillar arrays in a wafer fabrication process. The method includes fabricating a plurality of lines of photoresist on a hard mask stack wherein the hard mask stack is a multilayer hard mask stack, and depositing a spacer film on top of the plurality of lines of photoresist. The method further includes etching the spacer film to remove the spacer film from the top of the plurality of lines of photoresist and stripping the plurality of lines of photoresist to leave behind two spacer lines for each resist line. The method concludes with etching the spacer lines and the hard mask stack to yield an array of pillars.

In one embodiment, the present invention is implemented as a method for manufacturing an MRAM device. The method includes fabricating a plurality of lines of photoresist on a hard mask stack wherein the hard mask stack is a multilayer hard mask stack, and depositing a spacer film on top of the plurality of lines of photoresist. The method further includes etching the spacer film to remove the spacer film from the top of the plurality of lines of photoresist and stripping the plurality of lines of photoresist to leave behind to spacer lines for each resist line. The method concludes with etching the spacer lines and the hard mask stack to yield an array of pillars.

The foregoing is a summary and thus contains, by necessity, simplifications, generalizations and omissions of detail; consequently, those skilled in the art will appreciate that the summary is illustrative only and is not intended to be in any way limiting. Other aspects, inventive features, and advantages of the present invention, as defined solely by the claims, will become apparent in the non-limiting detailed description set forth below.

### BRIEF DESCRIPTION OF THE DRAWINGS

The present invention is illustrated by way of example, and not by way of limitation, in the figures of the accompanying drawings and in which like reference numerals refer to similar elements.

FIG. 1 shows a diagram illustrating examples of critical dimension, feature size, and pitch in accordance with one embodiment of the present invention.

FIG. 2 shows the steps of a photolithography patterning process 200 for fabricating an array of pillars in accordance with one embodiment of the present invention.

FIG. 3 shows the continuing steps of a photolithography patterning process 300 for fabricating an array of pillars in accordance with one embodiment of the present invention.

FIG. 4 shows the continuing steps of a photolithography patterning process 400 for fabricating an array of pillars in accordance with one embodiment of the present invention.

FIG. 5 shows a flowchart of the steps of a process for fabricating an array of pillars for an MRAM device in accordance with one embodiment of the present invention.

### DETAILED DESCRIPTION

Reference will now be made in detail to the preferred embodiments of the present invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of embodiments of the present invention, numerous specific details are set forth in order to provide a thorough understanding of the present invention. However, it will be recognized by one of ordinary skill in the art that the present invention may be practiced without these specific details. In other instances, well-known methods, procedures, components, and circuits have not been described in detail as not to unnecessarily obscure aspects of the embodiments of the present invention.

### A Photolithographic Method for Fabricating Dense Pillar Arrays Using Spacers as a Pattern

Embodiments of the present invention implement a method for fabricating an array of pillars. The method includes fabricating a plurality of lines of photoresist on a hard mask stack and depositing a spacer film on top of the plurality of lines of photoresist. The method further includes etching the spacer film to remove the spacer film from the top of the plurality of lines of photoresist and stripping the plurality of lines of photoresist to leave behind to spacer lines for each resist line. The method concludes with etching the spacer lines and the hard mask stack to yield an array of pillars.

In this manner, embodiments of the present invention provide a fabrication method in which the pattern density of the pillars can be increased beyond the limitations of photolithography tools. Embodiments of the present invention advantageously utilize techniques which are known for line and space patterning. Embodiments of the present invention implement a technique which extends the density of pillar patterning for MRAM MTJ applications.

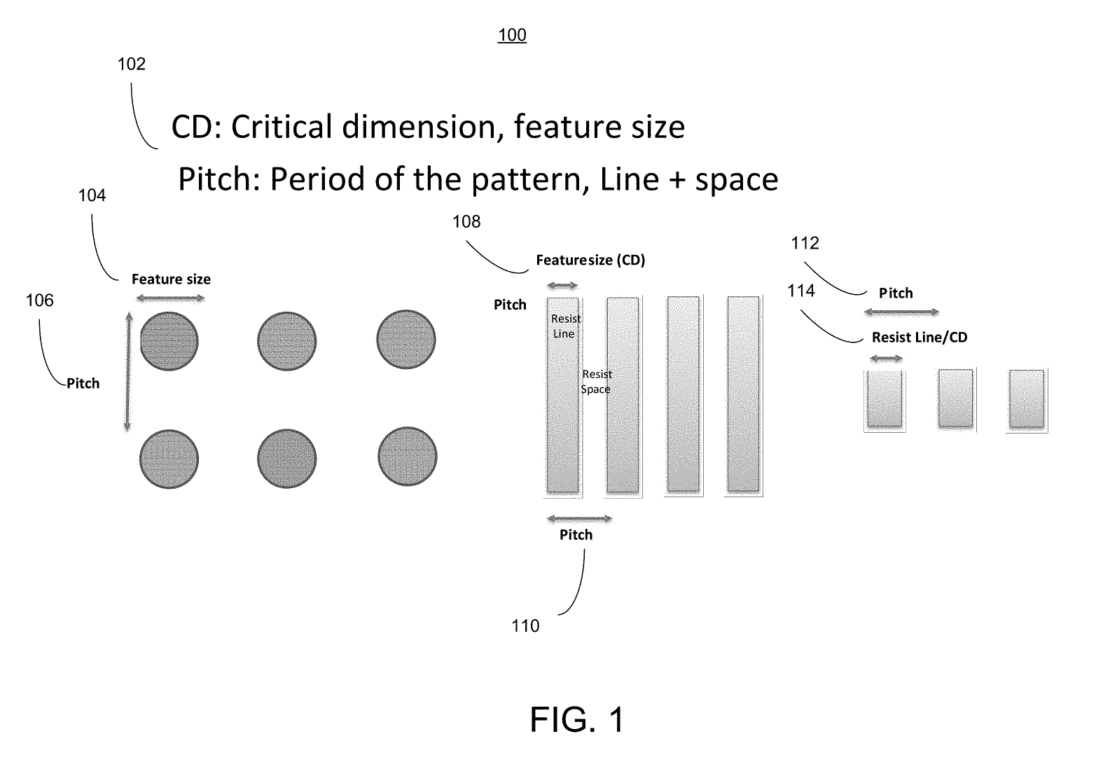

FIG. 1 shows a diagram 100 illustrating examples of critical dimension, feature size, and pitch in accordance with one embodiment of the present invention. The critical dimension feature size and pitch 102 comprise key factors in the density of a pillar array used for MRAM fabrication. The feature size 104 refers to the smallest size of a feature they can be patterning using optical lithography tools. The pitch 106 refers to the minimum interval between adjacent features. The feature size critical dimension 108 shows how the smallest minimum size resist line and the smallest minimum resist space between the features, e.g., pitch 110, define the critical dimensions of the a given fabrication process. This is further illustrated by the depicted pitch 112 and resist line critical dimension 114.

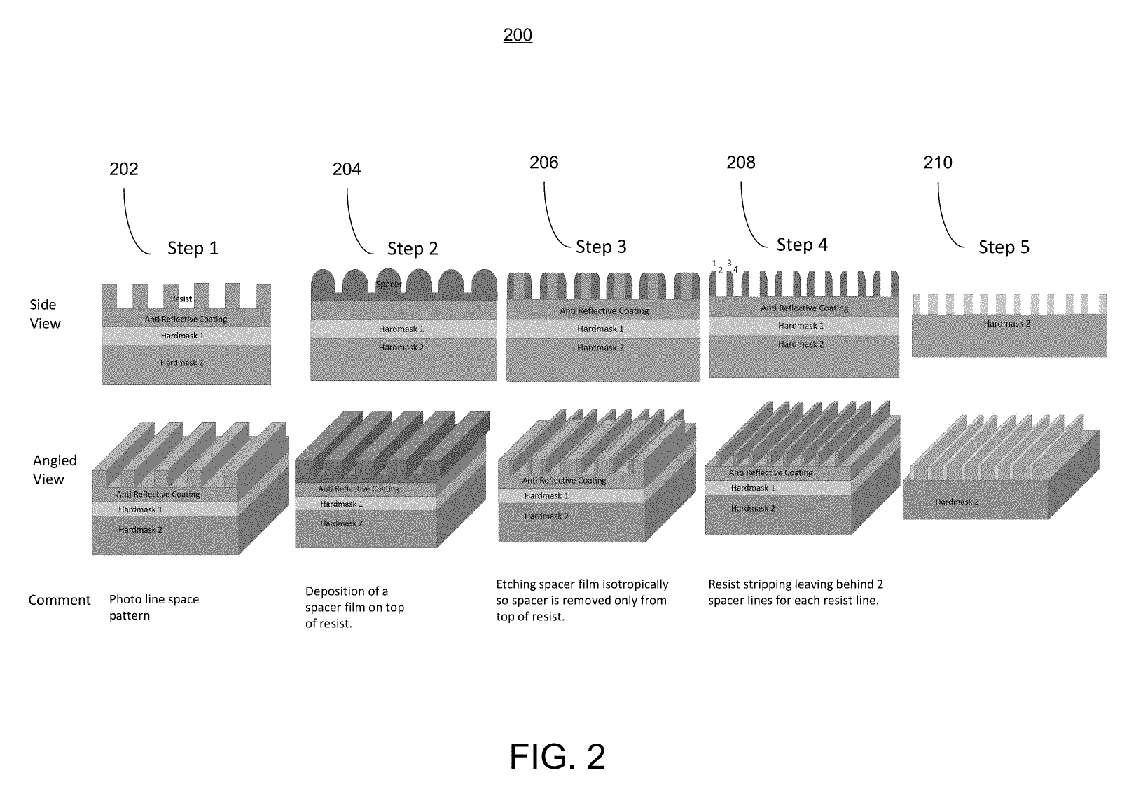

FIG. 2 shows the steps of a photolithography patterning process 200 for fabricating an array of pillars in accordance with one embodiment of the present invention. Process 200 shows an initial step 202 where photoresist lines have been formed on top of it antireflective coating which overlays a hard mask 1 and a hard mask 2. The upper part of step 202 shows a side view in the lower part of step 202 shows an angled view. In step 204, a spacer film is deposited on top of the photo resist lines. In step 206, the spacer film is etched isotropically so that the spacer is removed only from the top of the resist. In step 208, the resist is stripped leaving behind to spacer lines for each resist line, as shown. Step 210 shows the lines of hard mask 1 material on top of the hard mask 2 layer which remain after a reactive ion etching (ME) process.

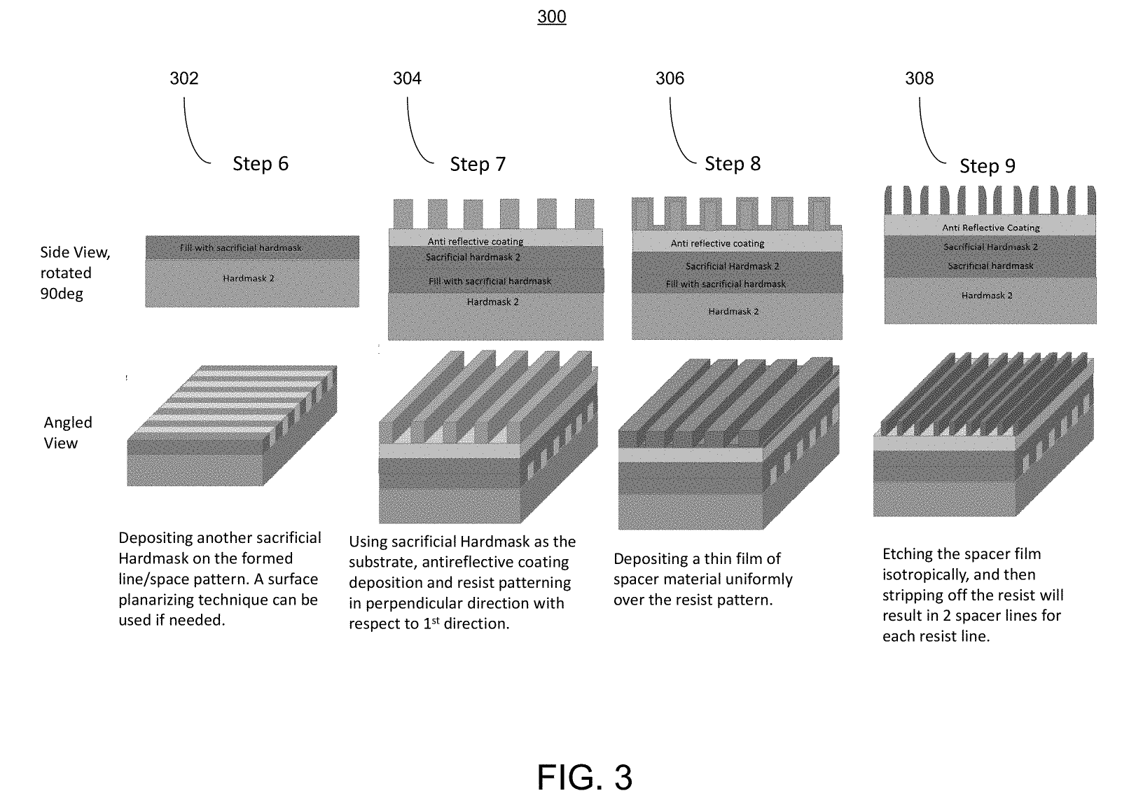

FIG. 3 shows the continuing steps of a photolithography patterning process 300 for fabricating an array of pillars in accordance with one embodiment of the present invention. In step 302, an additional sacrificial hard mask is deposited on the formed line and space pattern. A surface planarization technique can then be used to smooth the surface. In step 304, using the sacrificial hard mask as a substrate, and antireflective coating and resist patterning deposition is laid down in a perpendicular direction with respect to the first direction of step 302. In step 306, a thin film of spacer material is uniformly deposited over the resist pattern. In step 308, the spacer film is etched isotropically and then the resist is stripped off which results in 2 spacer lines for each resist line.

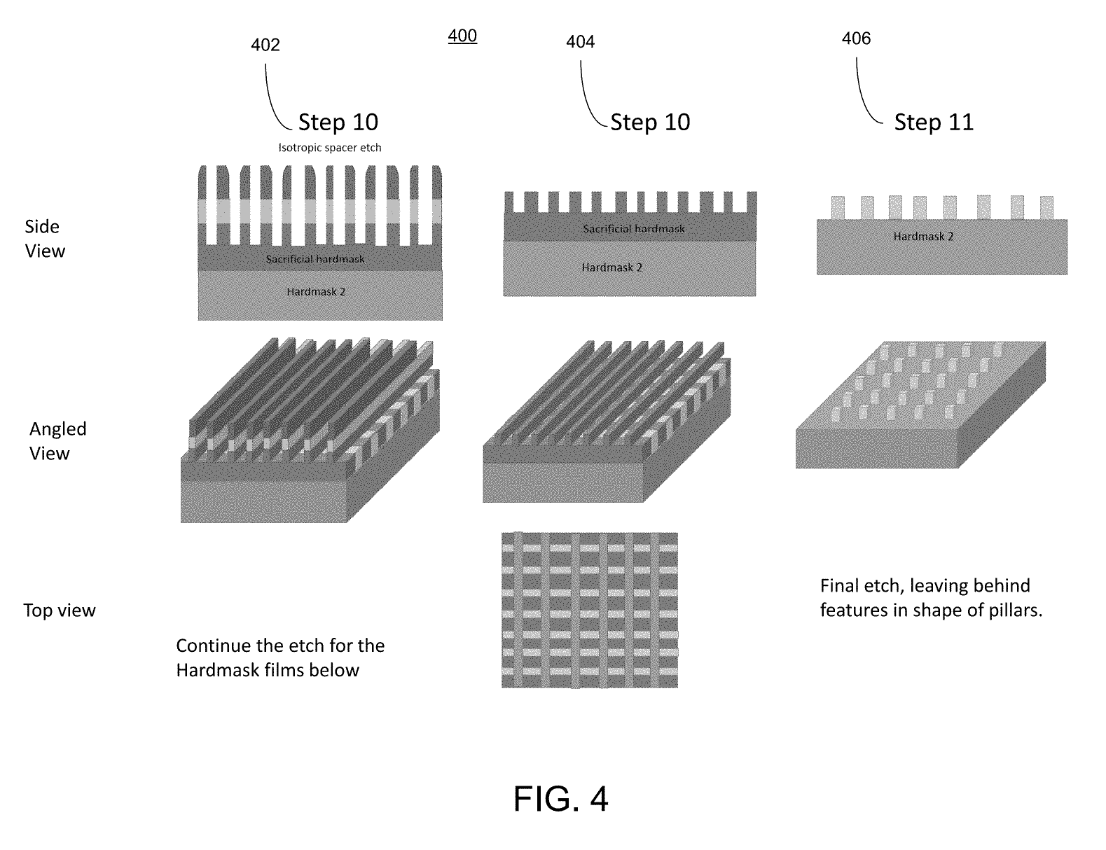

FIG. 4 shows the continuing steps of a photolithography patterning process 400 for fabricating an array of pillars in accordance with one embodiment of the present invention. In step 402, the edges continued into the hard masks films. In step 404, the remaining lines are shown on top of the sacrificial hard mask and the hard mask 2 layer. Step 406 shows the final result after the final etch, which leaves features in the shape of pillars on top of the hard mask 2 layer.

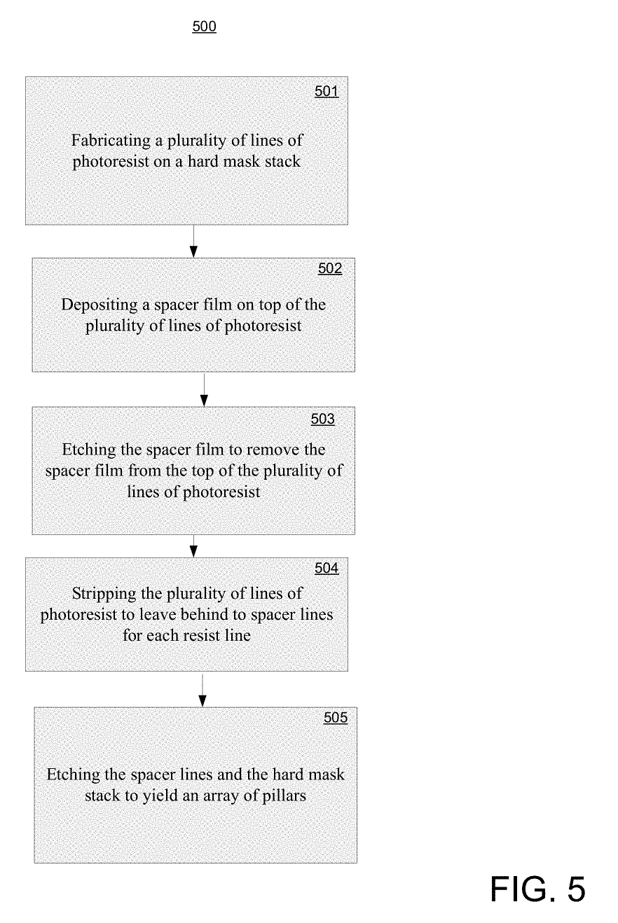

FIG. 5 shows a flowchart of the steps of a process 500 for fabricating an array of pillars. Process 500 begins in step 501, with fabricating a plurality of lines of photoresist on a hard mask stack. In step 502, process 500 continues with depositing a spacer film on top of the plurality of lines of photoresist. In step 503, process 500 continues with etching the spacer film to remove the spacer film from the top of the plurality of lines of photoresist. In step 504, process 500 continues with stripping the plurality of lines of photoresist to leave behind to spacer lines for each resist line. And in step 505, process 500 finishes by etching the spacer lines and the hard mask stack to yield an array of pillars.

In this manner, embodiments of the present invention provide a fabrication method in which the pattern density of the pillars can be increased beyond the limitations of photolithography tools. Embodiments of the present invention advantageously utilize techniques which are known for line and space patterning. Embodiments of the present invention implement a technique which extends the density of pillar patterning for MRAM MTJ applications.

The foregoing descriptions of specific embodiments of the present invention have been presented for purposes of illustration and description. They are not intended to be exhaustive or to limit the invention to the precise forms disclosed, and many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. A method for fabricating an array of pillars, the method comprising:
fabricating a plurality of lines of photoresist on a hard mask stack;
depositing a spacer film on top of the plurality of lines of photoresist;
etching the spacer film to remove the spacer film from the top of the plurality of lines of photoresist;
stripping the plurality of lines of photoresist to leave behind to spacer lines for each resist line;
etching the spacer lines and the hard mask stack to yield an array of pillars.

2. The method of claim 1, wherein the hard mask stack comprises a multilayer hard mask stack.

3. The method of claim 2, wherein the multilayer hard mask stack includes a bottom antireflective coating layer (BARC).

4. The method of claim 1, wherein reactive ion etching (REI) etches the hard mask stack to form hard mask pillars on top of an MTJ metal stack.

5. The method of claim 1, wherein the hard mask stack comprises a multilayer hard mask stack comprising a bottom antireflective coating (BARC) layer, a first hard mask layer, and a second hard mask layer.

6. The method of claim 5, wherein the first hard mask layer comprises tantalum nitride and the second hard mask layer comprises silicon oxide.

7. The method of claim 1, wherein wafers produced using photolithography patterning proceed through a subsequent MTJ fabrication process.

8. A method for producing pillar arrays in a wafer fabrication process, the method comprising:
fabricating a plurality of lines of photoresist on a hard mask stack, wherein the hard mask stack comprises a multilayer hard mask stack;
depositing a spacer film on top of the plurality of lines of photoresist;
etching the spacer film to remove the spacer film from the top of the plurality of lines of photoresist;
stripping the plurality of lines of photoresist to leave behind to spacer lines for each resist line;
etching the spacer lines and the hard mask stack to yield an array of pillars.

9. The method of claim 8, wherein a plurality of etches are implemented to yield the array of pillars.

10. The method of claim 8 wherein the multilayer hard mask stack includes a bottom antireflective coating layer (BARC).

11. The method of claim 8, wherein reactive ion etching (REI) etches the hard mask stack to form hard mask pillars on top of an MTJ metal stack.

12. The method of claim 8, wherein the hard mask stack comprises a multilayer hard mask stack comprising a bottom antireflective coating (BARC) layer, a first hard mask layer, and a second hard mask layer.

13. The method of claim 12, wherein the first hard mask layer comprises tantalum nitride and the second hard mask layer comprises silicon oxide.

14. The method of claim 8, wherein wafers produced using photolithography patterning proceed through a subsequent MTJ fabrication process.

15. A method for manufacturing an MRAM device, the method comprising:
fabricating a plurality of lines of photoresist on a hard mask stack;
depositing a spacer film on top of the plurality of lines of photoresist;
etching the spacer film to remove the spacer film from the top of the plurality of lines of photoresist;
stripping the plurality of lines of photoresist to leave behind to spacer lines for each resist line;
etching the spacer lines and the hard mask stack to yield an array of pillars.

16. The method of claim 15, wherein the hard mask stack comprises a multilayer hard mask stack.

17. The method of claim 16, wherein the multilayer hard mask stack includes a bottom antireflective coating layer (BARC).

18. The method of claim 15, wherein reactive ion etching (REI) etches the hard mask stack to form hard mask pillars on top of an MTJ metal stack.

19. The method of claim 15, wherein the hard mask stack comprises a multilayer hard mask stack comprising a bottom antireflective coating (BARC) layer, a first hard mask layer, and a second hard mask layer.

20. The method of claim 15, wherein the first hard mask layer comprises tantalum nitride and the second hard mask layer comprises silicon oxide.
